(19) United States
(12) Patent Application Publication
(10) Pub. No.: US 2011/0169895 A1
(43) Pub. Date: Jul. 14, 2011

(54) Inkjet print head, wafer level package and method of manufacturing the same

(75) Inventors: Jae Hun Kim, Seoul (KR); Yun Sung Kang, Suwon (KR); Won Chul Sim, Seongnam (KR); Ju Hwan Yang, Suwon (KR)

(73) Assignee: SAMSUNG ELECTRO-MECHANICS CO., LTD., Suwon (KR)

(21) Appl. No.: 12/923,286

(22) Filed: Sep. 13, 2010

(30) Foreign Application Priority Data
Jan. 12, 2010 (KR) 10-2010-0002732

(51) Int. Cl. B41J 2/045; H01L 21/18

(52) U.S. Cl. 347/68; 438/21; 257/E21.085

(57) ABSTRACT

There is provided an inkjet print head including an ink head and a chipping prevention portion. The ink head includes a nozzle for ejecting ink to the outside by a driving force of a piezoelectric actuator mounted on a surface of the ink head. The chipping prevention portion includes a cutting portion disposed at a side of the ink head and being cut so as to have a height lower than that of the nozzle.

### CROSS-REFERENCE TO RELATED APPLICATIONS

This application claims the priority of Korean Patent Application No. 10-2010-0002732 filed on Jan. 12, 2010, in the Korean Intellectual Property Office, the disclosure of which is incorporated herein by reference.

### BACKGROUND OF THE INVENTION

1. Field of the Invention

The present invention relates to an inkjet print head, a wafer level package, and a method of manufacturing the same, and more particularly, to an inkjet print head facilitating the cutting thereof in a wafer state, a wafer level package, and a method of manufacturing the same.

2. Description of the Related Art

In general, an inkjet print head converts electrical signals into physical impulses so that ink droplets are ejected through a small nozzle.

In recent years, a piezoelectric inkjet print head has been used in industrial inkjet printers. For example, it is used to directly form a circuit pattern by spraying ink prepared by melting a metal such as gold or silver onto a printed circuit board (PCB). It is also used for creating industrial graphics, or for the manufacturing of a liquid crystal display (LCD), an organic light emitting diode (OLED) and a solar cell.

In general, an inkjet print head includes an inlet and an outlet through which ink in a cartridge is drawn and ejected, a reservoir storing the ink being drawn, and a chamber transferring the driving force of an actuator so as to move the ink stored in the reservoir toward a nozzle.

According to the related art, an inkjet print head is manufactured in the state of a wafer capable of being cut into a plurality of chips. In order to cut the wafer into a plurality of inkjet print heads, a dicing process is performed.

However, when the dicing process is performed in the wafer state, chipping, which unnecessarily protrudes outwards of the diced portion of the wafer, may be caused.

This may cause problems such as the pollution or deformation of a nozzle when a nozzle surface of the inkjet print head is cleaned or the inkjet print head is coupled with an adapter. Therefore, there is a need for technologies in order to solve these problems.

### SUMMARY OF THE INVENTION

An aspect of the present invention provides an inkjet print head facilitating the dicing of individual ink heads in a wafer and a method of manufacturing the same.

According to an aspect of the present invention, there is provided an inkjet print head including: an ink head including a nozzle for ejecting ink to the outside by a driving force of a piezoelectric actuator mounted on a surface of the ink head; and a chipping prevention portion including a cutting portion disposed at a side of the ink head and being cut so as to have a height lower than that of the nozzle.

The chipping prevention portion may include the cutting portion having a tapered shape and provided at both sides of a plate having the nozzle formed therein.

The chipping prevention portion may be provided in a plate having the nozzle formed therein and a plate having the piezoelectric actuator mounted thereon.

The inkjet print head may further include an ink storage portion supplying ink to the ink head, and an adapter portion connecting the ink storage portion and the ink head by being interposed therebetween.

The adapter portion may include a mounting portion mounted on a surface of the ink head and a taper portion bent from the mounting portion along the cutting portion.

The inkjet print head may further include a sealing portion provided between the adapter portion and the ink head.

According to another aspect of the present invention, there is provided a method of manufacturing an inkjet print head, the method including: providing a wafer having a plurality of ink heads integrated therein; forming photoresist layers on the wafer in order to individually divide the wafer into the ink heads; forming cutting portions by etching the wafer; and manufacturing the individually divided ink heads by cutting the wafer along the cutting portions.

The cutting portions may be formed on both surfaces of the wafer.

The etching of the wafer may be performed by an anisotropic etching process along a crystalline surface of the wafer.

According to another aspect of the present invention, there is provided a wafer level package including: a body portion having a wafer shape and including a plurality of ink chambers and a plurality of nozzles respectively connected to the plurality of ink chambers; and chipping prevention portions including cutting portions provided in the body portion such that the ink chambers and the nozzles are cut in the unit of an ink head, wherein the cutting portions have a height lower than that of the nozzles.

The body portion may include a chamber wafer including the plurality of ink chambers storing ink therein, and a nozzle wafer bonded to the chamber wafer and including the nozzles connected to the ink chambers and ejecting the ink stored in the ink chambers to the outside.

The body portion may further include an intermediate wafer disposed between the chamber wafer and the nozzle wafer and including dampers connecting the ink chambers and the nozzles.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view schematically illustrating an inkjet print head according to an exemplary embodiment of the present invention;

FIG. 2 is a schematic cross-sectional view illustrating the inkjet print head of FIG. 1;

FIG. 3 is a schematic perspective view illustrating a wafer level package for manufacturing the inkjet print head of FIG. 2;

FIG. 4 is a schematic cross-sectional view illustrating an inkjet print head according to another exemplary embodiment of the present invention;

FIG. 5 is a schematic cross-sectional view illustrating an inkjet print head according to another exemplary embodiment of the present invention;

FIGS. 6 and 7 are schematic perspective and cross-sectional views illustrating an adapter portion in an inkjet print head according to another exemplary embodiment of the present invention, respectively;

FIG. 8 is a schematic cross-sectional view illustrating a method of manufacturing an inkjet print head according to an exemplary embodiment of the present invention; and

FIG. 9 is a schematic cross-sectional view illustrating a method of manufacturing an inkjet print head according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In addition, the same reference numerals will be used throughout the drawings to refer to the same or like elements.

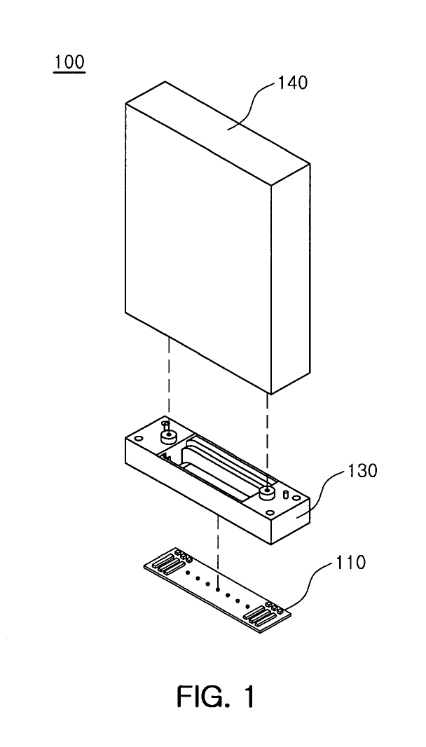

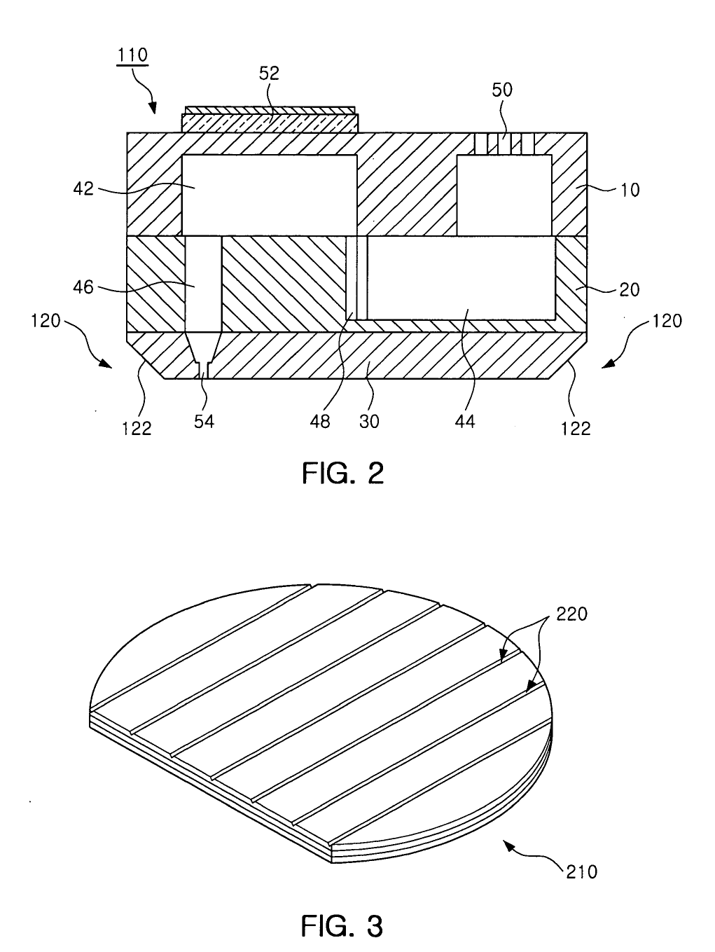

FIG. 1 is an exploded perspective view schematically illustrating an inkjet print head according to an exemplary embodiment of the present invention. FIG. 2 is a schematic cross-sectional view illustrating the inkjet print head of FIG. 1. FIG. 3 is a schematic perspective view illustrating a wafer level package for manufacturing the inkjet print head of FIG. 2.

With reference to FIGS. 1 through 3, an inkjet print head 100 may include an ink head 110 and a chipping prevention portion 120.

The ink head 110 ejects ink to the outside by the driving of a piezoelectric actuator 52 mounted on a surface thereof.

The ink head 110 may be made into a single body, and may be coupled with an adapter portion 130 and an ink storage portion 140. Here, the ink head 110 may include a nozzle 54 through which ink is ejected to the outside and an ink chamber 42 connected to the nozzle 54.

The chipping prevention portion 120 may include a cutting portion 122 of the ink head 110. The cutting portion 122 may have a height lower than that of the nozzle 54. In this embodiment, the cutting portion 122 may be formed to be tapered at both sides of a nozzle plate 30 in which the nozzle 54 is formed.

Here, the tapered shape of the cutting portion 122 may be obtained by an etching process. The chipping prevention portion 120 is subjected to an anisotropic etching process along a crystalline surface of a wafer so that it is naturally tapered thereby.

In general, when a wafer, not including the chipping prevention portion 120, is cut into chips, chipping, which unnecessarily protrudes outwards of a cut portion of the ink head 110, may be caused. This chipping may cause problems such as the pollution or deformation of the nozzle 54 when a nozzle surface of the inkjet print head being cut is cleaned or the inkjet print head is coupled with an adapter.

However, since the inkjet print head 100 according to this embodiment includes the chipping prevention portion 120 including the cutting portion 122 having a height lower than that of the nozzle 54, this prevents the occurrence of chipping that may be caused during a dicing process, thereby avoiding the pollution or deformation of the nozzle 54.

With reference to FIG. 3, a wafer level package for an inkjet print head may include a body portion 210 and chipping prevention portions 220.

The body portion 210 may be formed in a circular wafer shape. The body portion 210 includes a plurality of ink chambers and a plurality of nozzles individually connected to the ink chambers. The body portion 210 is cut in the unit of an inkjet print head to thereby form inkjet print heads.

Specifically, the body portion may include a chamber wafer having the plurality of ink chambers storing ink therein and a nozzle wafer bonded to the chamber wafer and having the plurality of nozzles individually connected to the plurality of ink chambers in order to eject the ink stored in the ink chambers to the outside.

The body portion may further include an intermediate wafer disposed between the chamber wafer and the nozzle wafer and having dampers connecting the ink chambers and the nozzles.

Also, the chipping prevention portions 220 have cutting portions on the body portion 210 so that the ink chambers and the nozzles may be cut in the unit of an inkjet print head. The cutting portions may have a height lower than that of the nozzles.

Hereinafter, the elements depicted in FIGS. 1 and 2 will be described in detail.

The ink head 110 may include a chamber plate 10, an intermediate plate 20, and the nozzle plate 30.

The chamber plate 10 may include the ink chamber 42, and an ink inlet 50 through which ink is drawn in. Here, the ink inlet 50 is connected to a reservoir 44, and the reservoir 44 supplies the ink to the ink chamber 42 through a restrictor 48.

The ink chamber 42 is disposed under a portion on which the piezoelectric actuator 52 is mounted. Here, a portion of the chamber plate 10 that forms the ceiling of the ink chamber 42 serves as a vibration plate.

Therefore, when a driving signal is applied to the piezoelectric actuator 52 in order to eject ink, the piezoelectric actuator 52 and the vibration plate thereunder are deformed to change the internal volume of the ink chamber 42.

This increases the pressure inside the ink chamber 42, so that the ink inside the ink chamber 42 is ejected to the outside through a damper 46 and the nozzle 54.

The piezoelectric actuator 52 may have electrodes electrically connected to the upper and lower surfaces thereof. The piezoelectric actuator 52 may be formed of Lead Zirconate Titanate (PZT) ceramics. However, the invention is not limited to the piezoelectric actuator 52, and a variety of actuators such as a thermal actuator may be substituted therefor.

The intermediate plate 20 may include the reservoir 44 having a large length extending in a longitudinal direction and the damper 46 connecting the nozzle 54 and the ink chamber 42.

The reservoir 44 is supplied with ink through the ink inlet 50 and supplies the ink to the ink chamber 42. The reservoir 44 and the ink chamber 42 are connected with each other through the restrictor 48.

The damper 46 receives the ink ejected from the ink chamber 42 by the driving of the piezoelectric actuator 52 and ejects the received ink to the outside through the nozzle 54.

The damper 46 may have a multi-stage configuration by which the amount of ink received from the ink chamber 42 and the amount of ink ejected through the nozzle 54 can be controlled.

The ink storage portion 140 may have a space for storing ink therein so as to supply ink to the ink head 110. The ink inside the ink storage portion 140 flows into the ink head 110 through the adapter portion 130.

The adapter portion 130 has a size corresponding to that of the ink storage portion 140, serves to transfer the ink to the ink head 110, and is structurally configured to be a single module. Therefore, the adapter portion 130 may be interposed between the ink storage portion 140 and the ink head 110.

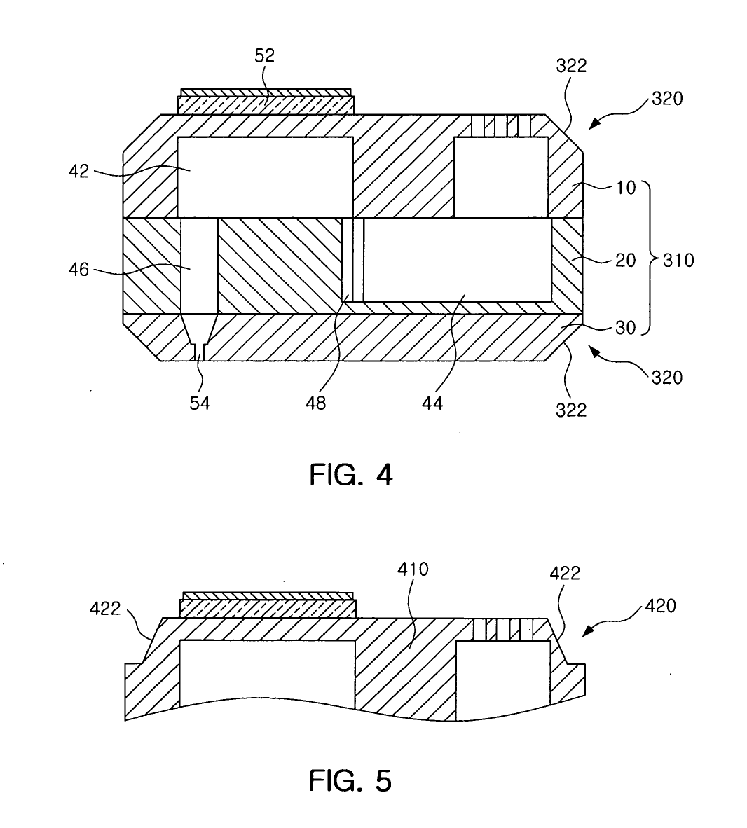

FIG. 4 is a schematic cross-sectional view illustrating an inkjet print head according to another exemplary embodiment of the present invention.

With reference to FIG. 4, an ink head 310 has the substantially same construction as that of the aforementioned embodiment, so a detailed description thereof will be omitted.

Here, chipping prevention portions 320 include cutting portions 322 in the ink head 310 so that the ink chambers 42 and the nozzles 54 are cut in the unit of an inkjet print head. The cutting portions 322 may have a height lower than that of the nozzles 54.

Here, the cutting portions 322 may be formed at both sides of the chamber plate 10 in which the ink chambers 42 are formed and on which the piezoelectric actuators 52 are mounted, as well as both sides of the nozzle plate 30 in which the nozzles 54 are formed.

The above-described structure according to this embodiment prevents the occurrence of chipping that may be caused during a dicing process.

FIG. 5 is a schematic cross-sectional view illustrating an inkjet print head according to another exemplary embodiment of the present invention.

With reference to FIG. 5, an ink head 410 has the substantially same construction as that of the aforementioned embodiment, so a detailed description thereof will be omitted.

Here, chipping prevention portions 420 may be formed at both sides of the ink head 410. Cutting portions 422 may have a partially tapered shape and the sides thereof may be parallel to a surface of the ink head 410. Therefore, the chipping prevention portions 420 may have a stepped structure.

Here, the chipping prevention portions 420 are formed by naturally etching a crystalline surface of a wafer, i.e., along a [100] direction in the case of silicon.

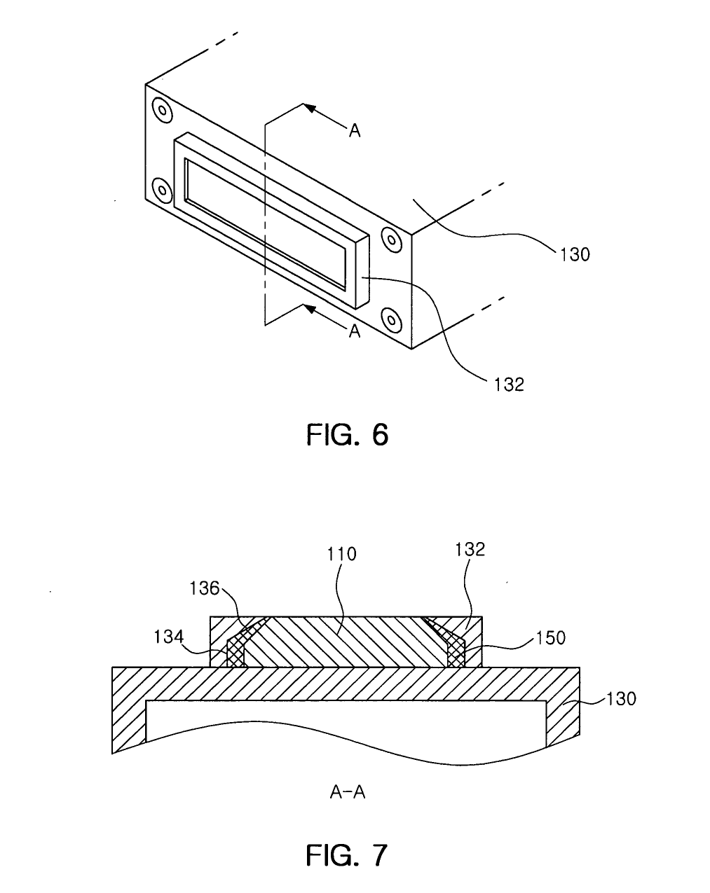

FIGS. 6 and 7 are schematic perspective and cross-sectional views illustrating an adapter portion in an inkjet print head according to another exemplary embodiment of the present invention, respectively.

With reference to FIGS. 6 and 7, the adapter portion 130 has the same size as that of the ink storage portion, serves to transfer ink to the ink head 110, and is structurally configured to be a single module.

The adapter portion 130 may include a fixing portion 132 in order to structurally fix the ink head 110.

Here, the fixing portion 132 is integrated with the body of the adapter portion 130 and is protruded from a surface thereof. In order to correspond to the chipping prevention portion 120 of the ink head 110, the inner surface of the fixing portion 132 may include a mounting portion 134 mounted on a surface of the ink head 110 and a taper portion 136 bent from the mounting portion 134 in a tapered manner. Due to the structure of the fixing portion 132, the adapter portion 130 may stably receive the ink head 110.

The inkjet print head may further include a sealing portion 150 disposed between the adapter portion 130 and the ink head 110. Here, the sealing portion 150 may be formed of rubber so that when the inkjet print head vibrates, the sealing portion 150 may absorb the vibratory force. However, the sealing portion 150 may be formed of a variety of materials, or may not be included according to a designer's intention.

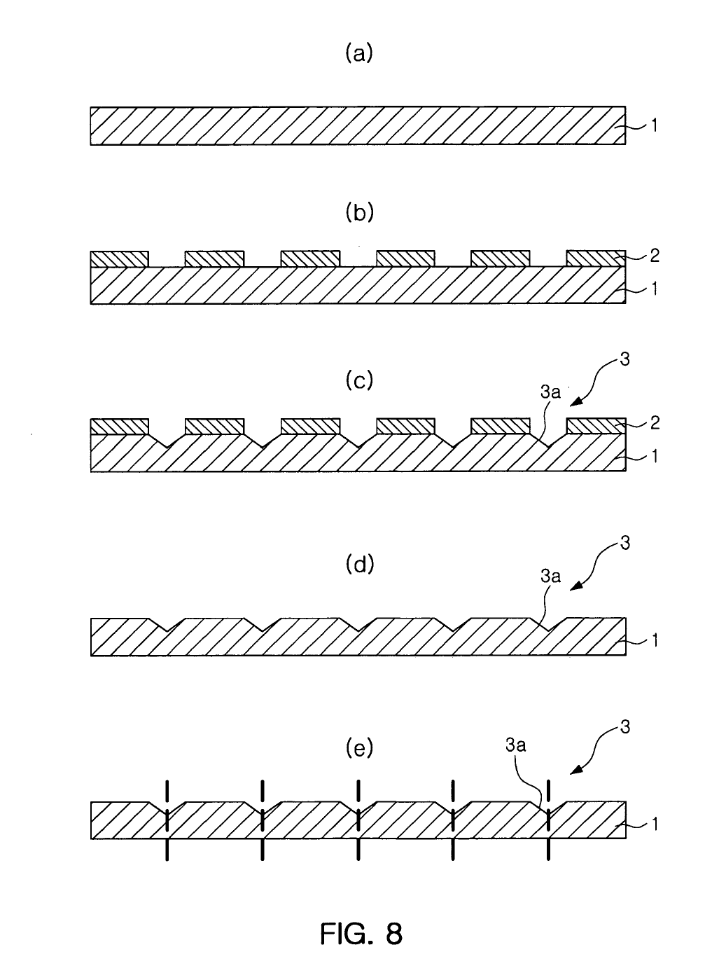

FIG. 8 is a cross-sectional view illustrating a method of manufacturing an inkjet print head according to an exemplary embodiment of the present invention.

With reference to FIG. 8A, a method of manufacturing an inkjet print head may include providing a wafer 1 having a plurality of ink heads formed therein.

At this time, the wafer 1 may include a body portion having a plurality of ink chambers and a plurality of nozzles individually connected to the ink chambers.

With reference to FIG. 8B, photoresist layers 2 are formed on the wafer 1 in order to divide the wafer 1 into individual ink heads. Here, the photoresist layers 2 are disposed at cut positions where chipping prevention portions 3 are formed.

With reference to FIG. 8C, the wafer 1 is etched to form cutting portions 3a.

At this time, the wafer 1 is etched along a crystalline surface formed on a surface of the wafer 1 such that the cutting portions 3a have a V-shape.

With reference to FIG. 8D, the photoresist layers 2 are removed from the wafer 1 having the cutting portions 3a formed therein.

As shown in FIG. 8E, the wafer 1 is cut along the cutting portions 3a to thereby manufacture the individual ink heads.

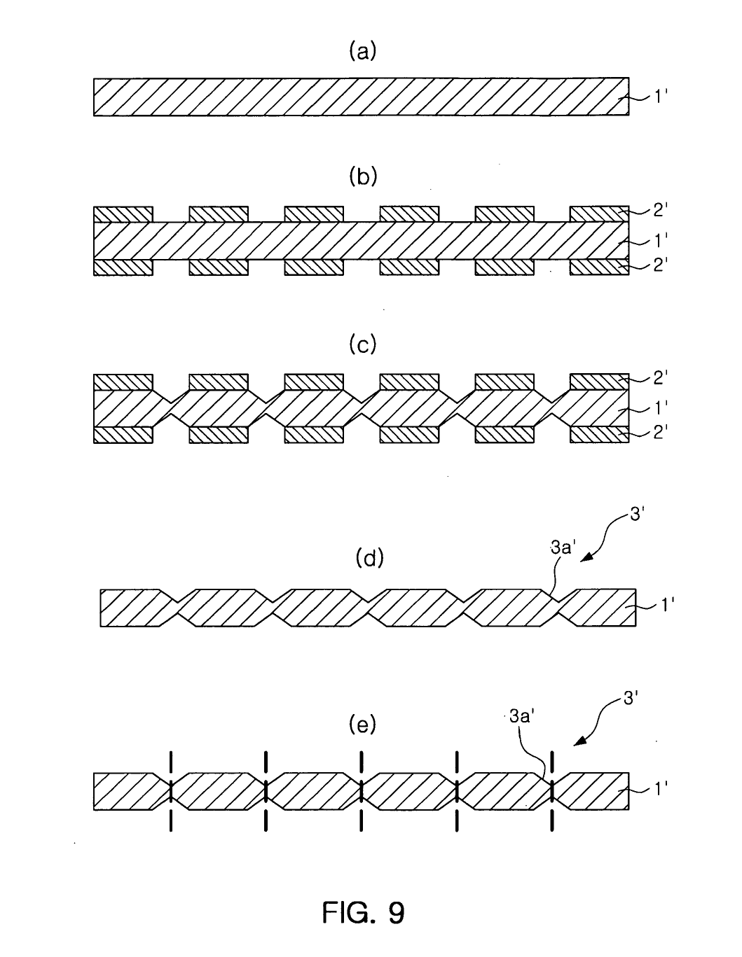

FIG. 9 is a cross-sectional view illustrating a method of manufacturing an inkjet print head according to an exemplary embodiment of the present invention.

With reference to FIG. 9A, a method of manufacturing an inkjet print head may include providing a wafer 1′ having a plurality of ink heads formed therein.

At this time, the wafer 1′ may include a body portion having a plurality of ink chambers and a plurality of nozzles individually connected to the ink chambers.

With reference to FIG. 9B, photoresist layers 2′ are formed on both surfaces of the wafer 1′ in order to divide the wafer 1′ into individual ink heads. Here, the photoresist layers 2′ are formed at cut positions where chipping prevention portions 3′ are formed.

With reference to FIG. 9C, the wafer 1′ is etched to form cutting portions 3a′.

At this time, the wafer 1′ is etched along crystalline surfaces formed on the both surfaces of the wafer 1′ such that the cutting portions 3a′ have a V-shape.

With reference to FIG. 9D, the photoresist layers 2′ are removed from the wafer 1′ having the cutting portions 3a′ formed therein.

As shown in FIG. 9E, the wafer 1′ is cut along the cutting portions 3a′ to thereby manufacture the individual ink heads.

Since the method of manufacturing the inkjet print head according to the above-described embodiments includes forming the chipping prevention portions 3 and 3′ and the cutting portions 3a and 3a′ of the wafer 1 and 1′, chipping, which unnecessarily protrudes outwards during the wafer cutting, may be prevented.

As set forth above, in an inkjet print head, a wafer level package, and a method of manufacturing the same according to exemplary embodiments of the invention, a chipping prevention portion is included in such a manner that a cutting portion of an ink head has a height lower than that of a nozzle, whereby chipping that may be caused during a dicing process is prevented. Accordingly, the pollution or deformation of the nozzle is avoided.

While the present invention has been shown and described in connection with the exemplary embodiments, it will be apparent to those skilled in the art that modifications and variations can be made without departing from the spirit and scope of the invention as defined by the appended claims.

What is claimed is:

1. An inkjet print head comprising:
an ink head including a nozzle for ejecting ink to the outside by a driving force of a piezoelectric actuator mounted on a surface of the ink head; and
a chipping prevention portion including a cutting portion disposed at a side of the ink head and being cut so as to have a height lower than that of the nozzle.

2. The inkjet print head of claim 1, wherein the chipping prevention portion includes the cutting portion having a tapered shape and provided at both sides of a plate having the nozzle formed therein.

3. The inkjet print head of claim 1, wherein the chipping prevention portion is provided in a plate having the nozzle formed therein and a plate having the piezoelectric actuator mounted thereon.

4. The inkjet print head of claim 1, further comprising:
an ink storage portion supplying ink to the ink head; and
an adapter portion connecting the ink storage portion and the ink head by being interposed therebetween.

5. The inkjet print head of claim 4, wherein the adapter portion includes a mounting portion mounted on a surface of the ink head and a taper portion bent from the mounting portion along the cutting portion.

6. The inkjet print head of claim 4, further comprising a sealing portion provided between the adapter portion and the ink head.

7. A method of manufacturing an inkjet print head, the method comprising:
providing a wafer having a plurality of ink heads integrated therein;
forming photoresist layers on the wafer in order to individually divide the wafer into the ink heads;
forming cutting portions by etching the wafer; and
manufacturing the individually divided ink heads by cutting the wafer along the cutting portions.

8. The method of claim 7, wherein the cutting portions are formed on both surfaces of the wafer.

9. The method of claim 7, wherein the etching of the wafer is performed by an anisotropic etching process along a crystalline surface of the wafer.

10. A wafer level package comprising:
a body portion having a wafer shape and including a plurality of ink chambers and a plurality of nozzles respectively connected to the plurality of ink chambers; and
chipping prevention portions including cutting portions provided in the body portion such that the ink chambers and the nozzles are cut in the unit of an ink head,
wherein the cutting portions have a height lower than that of the nozzles.

11. The wafer level package of claim 10, wherein the body portion comprises:
a chamber wafer including the plurality of ink chambers storing ink therein; and
a nozzle wafer bonded to the chamber wafer and including the nozzles connected to the ink chambers and ejecting the ink stored in the ink chambers to the outside.

12. The wafer level package of claim 11, wherein the body portion further comprises an intermediate wafer disposed between the chamber wafer and the nozzle wafer and including dampers connecting the ink chambers and the nozzles.
